(19) United States
(12) Patent Application Publication
(10) Pub. No.: US 2019/0225536 A1
(43) Pub. Date: Jul. 25, 2019

(54) Item Comprising an Organic-Inorganic Layer with Low Refractive Index Obtained by Oblique Angle Deposition

(71) Applicants: CORPORATION DE L'ECOLE POLYTECHNIQUE DE MONTREAL, Montreal (CA); Essilor International, Charenton-le-Pont (FR)

(72) Inventors: William TROTTIER-LAPOINTE, Montreal (CA); Oleg ZABEIDA, Montreal (CA); Ludvik MARTINU, Montreal (CA); Thomas SCHMITT, Montreal (CA); Karin SCHERER, Charenton-le-Pont (FR)

(21) Appl. No.: 16/300,319

(22) PCT Filed: May 9, 2017
(86) PCT No.: PCT/FR2017/051103

§ 371 Date: Nov. 9, 2018

(30) Foreign Application Priority Data
May 9, 2016 (FR) 1654138

(51) Int. Cl. C03C 17/42; C23C 14/22; G02B 1/111

(52) U.S. Cl. CPC C03C 17/42; C23C 14/226; G02B 1/111; C03C 2217/73; C03C 2217/78; C03C 2218/151; C03C 2217/213

(57) ABSTRACT

The invention relates to an item comprising a substrate having at least one first main surface coated with an organic-inorganic layer of a material obtained by vacuum deposition of at least one metal oxide B, preferably having a refraction index no higher than 1.53, and at least one organic compound, said layer having a refractive index no higher than 1.45, and said metal oxide having been deposited by oblique angle deposition.

The present invention relates generally to an article, preferably an optical article, in particular an ophthalmic lens, possessing a layer of organic-inorganic nature, combining high mechanical properties and a very low refractive index, and also to a process for preparing such an article.

It is known practice to coat optical articles such as ophthalmic lenses or screens, whether they are mineral or organic, with interference coatings, which are generally formed from a multilayer stack of dielectric mineral materials such as SiO, SiO₂, Si₃N₄, TiO₂, ZrO₂, Al₂O₃, MgF₂ or Ta₂O₅. An antireflective coating makes it possible to prevent the formation of spurious reflections that are an annoyance to the wearer and the people with whom he is speaking, in the case of an ophthalmic glass. A reflective coating produces the reverse effect, i.e. it increases the reflection of the light rays. Such a type of coating is used, for example, to obtain a mirror effect in sunglass lenses.

One of the problems encountered for all types of mineral interference coatings is their fragility mainly due to their mineral nature. There may be difficulty in making these coatings undergo substantial deformation or expansion, since the stress experienced is often reflected by cracking that propagates over the entire surface of the interference coating, generally making it unusable. Thus, interference coatings that are entirely of inorganic nature have a tendency to crack, this also occurring in the case of small degrees of deformation. During the trimming and fitting of a lens at an optician's practice, the lens undergoes mechanical deformations which can produce cracks in the mineral reflective or antireflective interference coatings, in particular when the operation is not performed with care. Depending on the number and size of the cracks, they may interfere with the wearer's view and prevent the lens from being sold. Furthermore, while the treated organic lenses are being worn, scratches can appear. In mineral interference coatings, some scratches lead to cracking, making the scratches more visible because of scattering of light.

Patent application WO 2013/098531, in the name of the Applicant, describes an article with improved thermomechanical performance, comprising a substrate having at least one main surface coated with a multilayer interference coating, said coating comprising a layer not formed from inorganic precursor compounds with a refractive index of less than or equal to 1.55, which may constitute the outer layer of the interference coating, and which has been obtained by deposition, under an ion beam, of activated species derived from at least one precursor compound in gaseous form of silico-organic nature such as octamethylcyclotetrasiloxane (OMCTS).

Patent application WO 2014/199103, in the name of the Applicant, describes a multilayer interference coating obtained according to similar technology, starting from a silico-organic precursor such as 2,4,6,8-tetramethylcyclotetrasiloxane (TMCTS).

The use of materials with a very low refractive index (n≤1.43) in antireflective coatings is advantageous, since such a refractive index makes it possible to obtain better antireflective performance (lower coefficients of reflection) without increasing the number of layers of the coating. However, to exploit the low refractive index, it is preferable to use the material under consideration as outer layer in contact with the air, or with a surface layer of another material of very low thickness (<10-15 nm). The existing materials with a low refractive index, such as MgF₂, do not make it possible to obtain good mechanical strength, which renders their use in optical applications prohibitive. The material MgF₂ is moreover very water-sensitive. Use of hollow or porous materials is another solution for ensuring a low refractive index, but these materials are generally very moisture-sensitive.

One object of the invention is to propose an efficient means for satisfactorily reducing the inherent fragility of mineral interference coatings. The invention is directed toward a coating, especially an interference coating, and in particular an antireflective coating, which has improved mechanical properties, while retaining a low refractive index, preferably with good adhesion properties. Another object of the invention is to provide a process for manufacturing an interference coating which is simple, easy to perform and reproducible.

Among the many variables which have an influence on the growth of a film in terms of density, crystal structure and morphology, the angle of incidence θ between the direction of the stream of particles to be deposited and the normal to the surface of the substrate plays a fundamental role. Generally, the stream of particles contributing toward the growth of a layer or coating reaches the surface of the substrate parallel to the normal to the surface of this substrate. The concept of glancing-angle deposition (GLAD) described, for example, in U.S. Pat. Nos. 5,866,204 and 6,206,065, consists in modifying the direction of the stream of particles such that it reaches the surface of the substrate not perpendicular to this surface, but at a glancing angle θ, which is generally high.

In the present patent application, a deposition is considered to have been made at a glancing angle if the angle θ between the direction of the stream of particles to be deposited and the normal to the surface of the substrate is greater than or equal to 30°. This angle is preferably greater than or equal to 60°, more preferably greater than or equal to 80°. Thus, deposition at a glancing angle makes it possible to obtain films that are less dense and less compact than in the case of deposition at a normal incidence (θ=0°), having an inclined structure oriented in the direction of the stream of particles, for instance a columnar or acicular structure. The problem with these materials is their great fragility, since said materials can sometimes be damaged by contact or by a simple stream of air.

Patent application WO 2007/062527 describes a columnar organic film, deposited in the vapor phase onto a substrate, said film having separate columns extending toward the exterior of the substrate and containing a microstructure producing optical effects in wavelengths within the visible range. The film, which is organic, is formed from a stream of vapors arriving on the substrate at an angle of greater than 70° relative to a direction perpendicular to the substrate.

The article by J. G. Van Dijken, M. D. Fleischauer and M. J. Brett, Organic Electronics 2011, 12, 2111-2119 describes the manufacture of zinc phthalocyanin nanostructured films comprising a network of inclined nanorods 40 nm in diameter formed by glancing-angle deposition, for the purpose of preparing organic photovoltaic devices.

The article by J. Q. Xi, M. F. Schubert, J. K. Kim, E. F. Schubert, M. Chen, S. -Y. Lin, W. Lui and J. A. Smart, Nature Photonics 2007, 1, 176-179 reveals that silica-based layers with refractive indices as low as 1.05 can be obtained by glancing-angle deposition. However, the high porosity and the fragility of these layers considerably limits their application in the field of optics.

The article by J. R. Sanchez-Valencia, R. Longtin, M. D. Rossell and P. Gröning, Appl. Mater. Interfaces 2016, 8, 8686-8693 discloses a layer with columnar microstructure obtained by co-deposition of an organic compound at a glancing angle, tris(8-hydroxyquinoline)aluminum(III), and of an inorganic compound under non-glancing conditions, zinc oxide ZnO. The organic compound is a sacrificial compound, removed in a second stage to give access to a very porous ZnO film with antireflective properties and a very low refractive index. The article teaches that zinc oxide cannot be directly deposited at a glancing angle to form an ordered structure, so it is necessary to use a sacrificial organic compound that can be deposited at a glancing angle. The applications targeted are photonics or the preparation of sensors.

The inventors have developed a transparent material having a layer with a (very) low refractive index, which may be as low as 1.18, which may be used in interference filters and which is resistant to water absorption, for meeting the targeted objectives. This material may be used in interference coatings to replace conventional materials with a very low refractive index such as hollow or porous silica, or MgF₂.

According to the invention, the layer of material with a low refractive index is formed by deposition of species in gaseous form, obtained from a precursor material of organic nature and from a precursor material of inorganic nature deposited at a glancing angle. It has improved mechanical properties while at the same time having a low refractive index and high transparency.

The targeted aims are thus achieved according to the invention by an article comprising a substrate having at least one main surface coated with a layer A of organic-inorganic nature of a material obtained by vacuum deposition of at least one metal oxide B and of at least one organic compound A1, said layer A having a refractive index of less than or equal to 1.45, and said metal oxide having been deposited by glancing-angle deposition.

For the purposes of the invention, a layer of organic-inorganic nature is a layer obtained from at least two precursors, one of organic nature, such as a purely organic compound or an organosilicon compound, and the other of inorganic nature, such as a metal oxide.

The organic-inorganic layer according to the invention (hybrid layer) combines noteworthy optical and mechanical strength properties, associated both with their nanostructure and with their chemical composition (organic-inorganic nature), which is very surprising, since materials with a low refractive index are generally very fragile, as are those which have undergone glancing-angle deposition. The interference coating according to the invention comprising such an organic-inorganic layer has better elasticity, i.e. it can be deformed more without suffering damage than a standard mineral interference coating.

The invention also relates to a process for manufacturing such an article, comprising at least the following steps:
supplying an article comprising a substrate having at least one main surface,
depositing onto said main surface of the substrate a layer A of organic-inorganic nature, by vacuum deposition of at least one metal oxide B and of at least one organic compound A1, said metal oxide being deposited by glancing-angle deposition,
recovering an article comprising a substrate having a main surface coated with a layer A of a material with a refractive index of less than or equal to 1.45.

The invention will be described in greater detail with reference to the attached drawing, in which

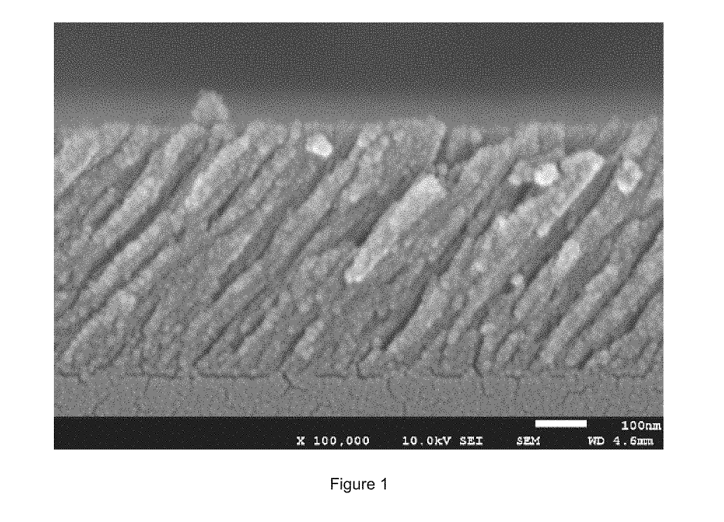

FIG. 1 represents an image obtained by scanning electron microscopy (SEM) of a cross section of layer A according to the invention.

In the present patent application, when an article comprises one or more coatings on its surface, the expression “to deposit a layer or a coating on the article” means that a layer or a coating is deposited on the uncovered (exposed) surface of the outer coating of the article, i.e. its coating furthest from the substrate.

A coating which is “on” a substrate or which has been deposited “on” a substrate is defined as a coating which (i) is positioned above the substrate, (ii) is not necessarily in contact with the substrate (although preferentially it is), i.e. one or more intermediate coatings may be positioned between the substrate and the coating in question, and (iii) does not necessarily completely cover the substrate (although preferentially it does cover it). When “a layer 1 is located under a layer 2”, it will be understood that layer 2 is further from the substrate than layer 1.

The article prepared according to the invention comprises a substrate, preferably a transparent substrate, having front and rear main faces, at least one of said main faces and preferably both main faces including at least one organic-inorganic layer A, which may be incorporated into an interference coating.

The term “rear face” (which is generally concave) of the substrate means the face which, when the article is being used, is the one closer to the wearer's eye. Conversely, the term “front face” (which is generally convex) of the substrate means the face which, when the article is being used, is the one further from the wearer's eye.

Although the article according to the invention can be any article, such as a screen, a glazing, a solar cell, protective goggles which can be used in particular in a working environment, a mirror or an article used in electronics, it preferably constitutes an optical article, better still an optical lens, especially a lens for optical instruments (microscopy, cameras, etc.), and better still a corrective or non-corrective ophthalmic lens, for spectacles, or an optical or ophthalmic lens blank, such as a semi-finished optical lens, in particular a spectacle lens. The lens may be a polarized or tinted lens or a photochromic or electrochromic lens.

Layer A according to the invention may be formed on at least one of the main faces of a bare substrate, that is to say an uncoated substrate, or on at least one of the main faces of a substrate already coated with one or more functional coatings.

The substrate of the article according to the invention is preferably an organic lens, for example made of thermoplastic or thermosetting plastic. This substrate may be chosen from the substrates mentioned in patent application WO 2008/062142, for example a substrate obtained by (co)polymerization of diethylene glycol bis(allyl carbonate), a substrate made of poly(thio)urethane or a substrate made of (thermoplastic) bisphenol A polycarbonate, denoted PC, a substrate obtained from episulfides, or a substrate made of PMMA (polymethyl methacrylate).

Before layer A is deposited on the substrate, which is optionally coated, for example with an abrasion-resistant and/or scratch-resistant coating, it is common practice to subject the surface of said optionally coated substrate to a physical or chemical activation treatment intended to increase the adhesion of layer A. This pretreatment is generally performed under vacuum. It may be a bombardment with energetic and/or reactive species, for example an ion beam (Ion Pre-Cleaning or IPC) or an electron beam, a corona discharge treatment, a glow discharge treatment, a UV treatment or a treatment by vacuum plasma, generally an oxygen or argon plasma. It may also be an acidic or basic surface treatment and/or a surface treatment with solvents (water or organic solvent). Several of these treatments can be combined. By virtue of these cleaning treatments, the cleanliness and reactivity of the surface of the substrate are optimized.

The term “energetic (and/or reactive) species” refers especially to ionic species having an energy preferably ranging from 1 to 300 eV, preferentially from 1 to 150 eV, better still from 10 to 150 eV and even better still from 40 to 150 eV. The energetic species may be chemical species, such as ions or radicals, or species such as photons or electrons.

The preferred pretreatment of the surface of the substrate is an ion bombardment treatment performed using an ion gun, the ions being particles formed from gas atoms from which one or more electron(s) have been stripped. Use is preferably made, as ionized gas, of argon (Ar⁺ ions), but also of oxygen or of mixtures thereof, under an acceleration voltage generally ranging from 50 to 200 V, a current density generally of between 10 and 100 μA/cm² on the activated surface, and generally under a residual pressure in the vacuum chamber which may range from 8×10⁻⁵ mbar to 2×10⁻⁴ mbar.

According to the invention, the organic-inorganic layer A constitutes a low-refractive-index layer, due to its refractive index of less than or equal to 1.45, preferably less than or equal to 1.44, better still less than or equal to one of the following values: 1.43; 1.42; 1.41; 1.40, 1.39, 1.38, 1.37, 1.36, better still less than or equal to 1.35 and even better still less than or equal to 1.30, 1.25 or 1.20. Its refractive index is preferably greater than or equal to 1.15. In the present patent application, a layer is said to be a low-refractive-index layer when its refractive index is less than or equal to 1.55, preferably less than or equal to 1.50 and better still less than or equal to 1.45. A layer is said to be a high-refractive-index layer when its refractive index is greater than 1.55, preferably greater than or equal to 1.6, better still greater than or equal to 1.8 and even better still greater than or equal to 2.0. Unless otherwise indicated, the refractive indices to which reference is made in the present invention are expressed at 25° C. for a wavelength of 550 nm.

The article according to the invention includes at least one layer A, which preferably constitutes a low-refractive-index layer of an interference coating, preferentially an antireflective coating. This interference coating may be a monolayer or multilayer coating. In one embodiment, the article according to the invention comprises a multilayer interference coating whose outer layer, i.e. the layer of the (interference) coating that is the furthest from the substrate in the stacking order, is a layer A according to the invention, which is preferentially directly deposited on a high-refractive-index layer.

In another embodiment, layer A according to the invention is the layer directly in contact with the outer layer of the interference coating, this outer layer of the interference coating preferably being a layer with a refractive index of less than or equal to 1.55 and a thickness preferably less than or equal to 30 nm, better still less than or equal to 10 or 15 nm. In this second case, layer A constitutes the penultimate layer of the interference coating, in the stacking order.

The interference coating may contain one or more layers A according to the invention, which may be identical or different.

In a first embodiment, all the low-refractive-index layers of the interference coating are identical or different layers A according to the invention.

In another embodiment of the invention, all the low-refractive-index layers of the interference coating according to the invention are of inorganic nature except for a layer A (that is to say that the other low-refractive-index layers of the interference coating preferably do not contain any organic compound).

Preferably, all the layers of the interference coating according to the invention are of inorganic nature except for layer A, which means that layer A preferably constitutes the only layer of organic-inorganic nature of the interference coating of the invention (the other layers of the interference coating preferably not containing any organic compound).

Layer A or said multilayer (interference) coating is preferably formed on an abrasion-resistant coating. The preferred abrasion-resistant coatings are coatings based on epoxysilane hydrolyzates including at least two, preferably at least three, hydrolyzable groups bonded to the silicon atom. The preferred hydrolyzable groups are alkoxysilane groups.

The interference coating may be any interference coating conventionally used in the field of optics, in particular of ophthalmic optics, except for the fact that it includes at least one layer A according to the invention. The interference coating may be, without limitation, an antireflective coating or a reflective (mirror) coating, preferably an antireflective coating.

An antireflective coating is defined as a coating, deposited on the surface of an article, which improves the antireflective properties of the final article. It makes it possible to reduce the reflection of light at the article-air interface over a relatively broad portion of the visible spectrum.

As is well known, interference coatings, preferably antireflective coatings, conventionally comprise a single-layer or multilayer stack of dielectric materials. These are preferably multilayer coatings, comprising high-refractive-index (HI) layers and low-refractive-index (LI) layers.

As it is possible to obtain very low refractive indices for layer A, a multilayer interference coating including layer A according to the invention may be obtained when the interference coating comprises, besides layer A, a layer with a refractive index of less than 1.55 and greater than the refractive index of layer A, and for which the difference in index with layer A is significant (typically greater than one of the following values: 0.2, 0.25, 0.3), to contribute toward the interference effect. In this case, the interference coating may include only these two layers.

HI layers are conventional high-refractive-index layers, well known in the art. They generally comprise one or more mineral oxides, such as, without limitation, zirconia (ZrO₂), titanium dioxide (TiO₂), tantalum pentoxide (Ta₂O₅), neodymium oxide (Nd₂O₅), hafnium oxide (HfO₂), praseodymium oxide (Pr₂O₃), praseodymium titanate (PrTiO₃), La₂O₃, Nb₂O₅, Y₂O₃, Al₂O₃, tungsten oxide such as WO₃, indium oxide In₂O₃ or tin oxide SnO₂. The preferred materials are TiO₂, Ta₂O₅, PrTiO₃, ZrO₂, SnO₂, In₂O₃ and mixtures thereof.

LI layers are also well known and may comprise, without limitation, SiO₂, MgF₂, ZrF₄, alumina (Al₂O₃) in a low proportion, AlF₃, and mixtures thereof, preferably SiO₂. Use may also be made of SiOF (fluorine-doped SiO₂) layers.

Generally, HI layers have a physical thickness ranging from 10 to 120 nm and LI layers have a physical thickness ranging from 10 to 120 nm, preferably from 10 to 110 nm.

The total thickness of the interference coating is preferably less than 1 micrometer, better still less than or equal to 800 nm and even better still less than or equal to 500 nm. The total thickness of the interference coating is generally greater than 100 nm, preferably greater than 150 nm.

More preferably, the interference coating, which is preferably an antireflective coating, comprises at least two low-refractive-index (LI) layers and at least two high-refractive-index (HI) layers. The total number of layers in the interference coating is preferentially less than or equal to 8 and better still less than or equal to 6.

It is not necessary for the HI and LI layers to alternate in the interference coating, although they can do so according to one embodiment of the invention. Two (or more) HI layers may be deposited on one another, just as two (or more) LI layers may be deposited on one another.

According to one embodiment of the invention, the interference coating comprises a sublayer. In this case, it generally constitutes the first layer of this interference coating in the order of deposition of the layers, i.e. the layer of the interference coating which is in contact with the subjacent coating (which is generally an abrasion-resistant and/or scratch-resistant coating) or with the substrate, when the interference coating is deposited directly on the substrate.

The term “sublayer of the interference coating” means a relatively thick coating used with the aim of improving the abrasion resistance and/or scratch resistance of said coating and/or of promoting its adhesion to the substrate or to the subjacent coating. The sublayer according to the invention may be chosen from the sublayers described in patent application WO 2010/109154. Preferentially, the sublayer has a thickness of 100 to 200 nm. It is preferentially exclusively mineral/inorganic in nature and preferentially consists of silica SiO₂.

The article of the invention can be rendered antistatic by means of incorporating, preferably in the interference coating, at least one electrically conductive layer. The term “antistatic” means the property of not retaining and/or developing an appreciable electrostatic charge. An article is generally considered as having acceptable antistatic properties when it does not attract and hold dust and small particles after one of its surfaces has been rubbed with an appropriate cloth.

The nature and the location in the stack of the electrically conductive layer that may be used in the invention are described in greater detail in patent application WO 2013/098531. It is preferably a layer with a thickness of 1 to 20 nm preferably comprising at least one metal oxide chosen from indium tin oxide (In₂O₃:Sn, tin-doped indium oxide, denoted ITO), indium oxide (In₂O₃) and tin oxide (SnO2).

The various layers of the interference coating (of which the optional antistatic layer forms part), other than the layer(s) A, are preferentially deposited by vacuum deposition according to one of the following techniques: i) by evaporation, optionally ion beam-assisted evaporation, ii) by ion beam sputtering, iii) by cathode sputtering or iv) by plasma-enhanced chemical vapor deposition. These various techniques are described in the publications “Thin Film Processes” and “Thin Film Processes II”, Vossen and Kern, Eds., Academic Press, 1978 and 1991, respectively. A particularly recommended technique is the vacuum evaporation technique. Preferably, each of the layers of the interference coating is deposited by vacuum evaporation.

Layer A is formed from a material obtained by vacuum deposition of two categories of precursors, in particular by coevaporation: at least one metal oxide B and at least one organic compound A1. It is considered in the present patent application that metalloid oxides belong to the general category of metal oxides, and the generic term “metal” also denotes metalloids. Preferably, the deposition is performed in a vacuum chamber, and the precursors are introduced or pass into a gaseous state in the vacuum chamber.

In one embodiment, the deposition of said layer A is not assisted by an ion source.

In another embodiment, the deposition of layer A is performed with assistance by an ion source, preferentially under ion bombardment, generally performed with an ion gun. This technique of deposition under an ion beam makes it possible to obtain activated species derived from at least one organic compound A1 and from at least one metal oxide B, in gaseous form. In this embodiment, the vacuum chamber includes an ion gun directed toward the substrates to be coated, which emits, toward said substrates, a beam of positive ions generated in a plasma within the ion gun. Preferably, the ions derived from the ion gun are particles consisting of gas atoms from which one or more electron(s) have been stripped and which are formed from a noble gas, oxygen or a mixture of two or more of these gases.

Without wishing to be limited by any theory, the inventors believe that the ion gun induces activation/dissociation of the precursor compound A and of the precursor metal oxide in a zone located a certain distance in front of the gun, which forms an organic-inorganic layer containing M—O—Si—CHx bonds, M denoting the metal atom of the metal oxide.

This deposition technique using an ion gun and a gaseous precursor, sometimes referred to as “ion beam deposition”, is described in particular, with only organic precursors, in patent U.S. Pat. No. 5,508,368.

According to the invention, preferentially, the only place in the chamber where a plasma is generated is the ion gun.

The ions may, if required, be neutralized before they exit the ion gun. In this case, the bombardment will still be regarded as being ion bombardment. The ion bombardment causes atomic rearrangement in and densification of the layer being deposited, which makes it possible to tamp it down while it is in the course of being formed.

During the implementation of the process according to the invention, the surface to be treated is preferentially bombarded with ions with a current density generally of between 20 and 1000 μA/cm², preferably between 30 and 500 μA/cm² and better still between 30 and 200 μA/cm², over the activated surface, and generally under a residual pressure in the vacuum chamber which may range from 6×10⁻⁵ mbar to 2×10⁻⁴ mbar and preferably from 8×10⁻⁵ mbar to 2×10⁻⁴ mbar. An argon and/or oxygen ion beam is preferably used. When a mixture of argon and oxygen is employed, the Ar/O₂ mole ratio is preferably 1, better still 0.75 and even better still ≤0.5. This ratio can be controlled by adjusting the gas flow rates in the ion gun. The argon flow rate preferably ranges from 0 to 30 sccm. The oxygen O₂ flow rate preferably ranges from 5 to 30 sccm, and rises in proportion as the flow rate of the precursor compounds of layer A increases.

The ions of the ion beam, preferentially derived from an ion gun, used during the deposition of layer A preferably have an energy ranging from 5 eV to 1000 eV, better still from 5 to 500 eV, preferentially from 75 to 150 eV, preferentially from 80 to 140 eV and better still from 90 to 110 eV. The activated species formed are typically radicals or ions.

In the event of ion bombardment during the deposition, it is possible to perform a plasma treatment concomitant or nonconcomitant with the ion-beam deposition of layer A. The layer is preferably deposited without assistance by a plasma on the substrates.

Said layer A is deposited in the presence of an oxygen source when the precursor compound A1 does not contain (or does not contain enough) oxygen atoms and when it is desired for layer A to contain a certain proportion of oxygen. Similarly, said layer A is deposited in the presence of a nitrogen source when the precursor compound A1 does not contain (or does not contain enough) nitrogen atoms and when it is desired for layer A to contain a certain proportion of nitrogen.

Generally, it is preferable to introduce oxygen gas with, if appropriate, a low content of nitrogen gas, preferably in the absence of nitrogen gas.

Besides layer A, other layers of the interference coating can be deposited under ion bombardment as described above, that is to say by using bombardment by means of an ion beam of the layer being formed, which ions are preferably emitted by an ion gun.

The preferred method for the vaporization of the precursor materials of layer A, performed under vacuum, is physical vapor deposition, in particular vacuum evaporation, generally combined with heating of the compounds to be evaporated. It may be deployed by using evaporation systems as diverse as a Joule-effect heat source (the Joule effect is the thermal manifestation of electrical resistance) or an electron gun for the liquid or solid precursors, it being possible for any other device known to a person skilled in the art to also be used.

The precursor compound A1 of layer A is preferably introduced into the vacuum chamber in which the articles according to the invention are prepared in gaseous form, while controlling its flow rate. It is preferably not vaporized inside the vacuum chamber (in contrast to the precursor metal oxide). The feed of the precursor compound A1 of layer A is located a distance away from the exit of the ion gun (when it is used) preferably ranging from 30 to 50 cm.

Preferably, the precursor metal oxide is preheated, so as to be in a molten state, and then evaporated. It is preferably deposited by vacuum evaporation using an electron gun in order to bring about its vaporization.

The precursor compound A1 and the precursor metal oxide are preferably deposited concomitantly (for example by coevaporation) or partially concomitantly, that is to say with overlapping of the steps of deposition of both precursors. In the latter case, the deposition of one of the two precursors begins before the deposition of the other, the deposition of the second precursor beginning before the end of the deposition of the first precursor. Typically, the precursor organic compound A is introduced concomitantly with the glancing-angle deposition of the metal oxide.

According to the invention, the metal oxide B, which is the precursor of layer A, is deposited by glancing-angle deposition.

The glancing-angle deposition is preferably performed at an angle between the normal to the surface of the substrate and the stream of particles of said metal oxide of greater than or equal to 60°, better still greater than or equal to one of the following values: 65°, 70°, 75°, 80°, 85°, 86°.

In one embodiment, the deposition is performed while the substrate is rotating about an axis substantially orthogonal to the surface of the substrate. When the substrate is an ophthalmic lens, the abovementioned axis preferably merges with the optical axis of the lens.

Depositing the precursor metal oxide of layer A at a high angle of incidence has the advantage of greatly reducing the refractive index of said layer, this refractive index being proportionately smaller the higher the angle of incidence θ between the normal to the surface of the substrate and the stream of metal oxide vapors.

This way of proceeding has an influence on the structure of layer A, which preferably has an inclined structure oriented in the direction of the vapor stream, typically a columnar microstructure, as shown in FIG. 1, which represents an image obtained by scanning electron microscopy (SEM) of a cross section of layer A according to the invention, corresponding to example 12 of the experimental section (but without rotation of the substrates). To obtain this image, a 5 nm gold layer was deposited so as to minimize the formation of charges and to improve the image resolution. The columns of the columnar structure are inclined by an angle α, which depends both on the flow rate (and thus on the partial pressure) of the organic compound A, and on the angle of incidence of the vapor stream. A high flow rate of this compound leads to less inclined and less isolated columns.

The precursor organic compound A1 of layer A is preferentially an organosilicon compound. In this case, it contains in its structure at least one silicon atom and at least one carbon atom. It preferably includes at least one Si—C bond and preferably includes at least one hydrogen atom. According to one embodiment, compound A1 comprises at least one nitrogen atom and/or at least one oxygen atom, preferably at least one oxygen atom.

The concentration of each chemical element (Si, O, C, H, N, etc.) in layer A may be determined using the Rutherford backscattering spectrometry (RBS) technique and elastic recoil detection analysis (ERDA).

The atomic percentage of metal (including metalloid) atoms in layer A preferably ranges from 5% to 30%, better still from 15% to 25%. The atomic percentage of carbon atoms in layer A preferably ranges from 10% to 25%, better still from 15% to 25%. The atomic percentage of hydrogen atoms in layer A preferably ranges from 10% to 40%, better still from 10% to 20%. The atomic percentage of oxygen atoms in layer A preferably ranges from 20% to 60%, better still from 35% to 45%.

The following compounds are nonlimiting examples of cyclic and noncyclic organic compounds A: octamethylcyclotetrasiloxane (OMCTS), decamethylcyclopentasiloxane, dodecamethylcyclohexasiloxane, hexamethylcyclotrisiloxane, hexamethyldisiloxane (HMDSO), octamethyltrisiloxane, decamethyltetrasiloxane, dodecamethylpentasiloxane, tetraethoxysilane, vinyltrimethylsilane, hexamethyldisilazane, hexamethyldisilane, hexamethylcyclotrisilazane, vinylmethyldiethoxysilane, divinyltetramethyldisiloxane, tetramethyldisiloxane, polydimethylsiloxane (PDMS), polyphenylmethylsiloxane (PPMS) or a tetraalkylsilane, such as tetramethylsilane.

Preferably, compound A1 includes at least one silicon atom bearing at least one alkyl group, preferably a C1-C4 alkyl group, better still at least one silicon atom bearing one or two identical or different alkyl groups, preferably C1-C4 alkyl groups, for example the methyl group.

The preferred precursor compounds A of layer A include an Si—O—Si group, better still a divalent group of formula (3):

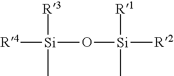

where R′¹ to R′⁴ independently denote linear or branched alkyl or vinyl groups, preferably C1-C4 groups, for example the methyl group, monocyclic or polycyclic aryl groups, hydroxyl groups or hydrolyzable groups. Nonlimiting examples of hydrolyzable groups are the following groups: H, halogen (chloro, bromo, iodo, etc.), alkoxy, aryloxy, acyloxy, —NR¹R², where R¹ and R² independently denote a hydrogen atom, an alkyl group or an aryl group, and —N(R³)—Si, where R³ denotes a hydrogen atom, a linear or branched alkyl group, preferably a C1-C4 alkyl group, or a monocyclic or polycyclic aryl group, preferably a monocyclic aryl group. Groups comprising an Si—O—Si chain unit are not considered to be “hydrolyzable groups” within the meaning of the invention. The preferred hydrolyzable group is the hydrogen atom.

According to another embodiment, the precursor compound A1 of layer A corresponds to the formula:

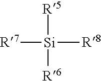

in which R′⁵, R′⁶, R′⁷ and R′⁸ independently denote hydroxyl groups or hydrolyzable groups, such as groups OR, in which R is an alkyl group.

According to a first embodiment, the compound A1 includes at least one silicon atom bearing two identical or different alkyl groups, preferably C1-C4 alkyl groups. According to this first embodiment, compound A1 is preferably a compound of formula (3) in which R′¹ to R′⁴ independently denote alkyl groups, preferably C1-C4 alkyl groups, for example the methyl group.

Preferably, the silicon atom(s) of compound A1 do not include any hydrolyzable group or hydroxyl group in this embodiment.

The silicon atom(s) of the precursor compound A1 of layer A are preferably solely bonded to alkyl groups and/or groups including an —O—Si or —NH—Si chain unit, so as to form an Si—O—Si or Si—NH—Si group. The preferred precursor compounds of layer A are OMCTS and HM DSO.

It is preferably a cyclic polysiloxane of formula (4):

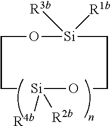

where n designates an integer ranging from 2 to 20, preferably from 3 to 8, and R^{1b} to R^{4b} independently represent linear or branched alkyl groups, preferably C1-C4 alkyl groups (for example the methyl group), vinyl groups, aryl groups or a hydrolyzable group. The preferred members belonging to this group are the octaalkylcyclotetrasiloxanes (n=3), preferably octamethylcyclotetrasiloxane (OMCTS). In some cases, layer A is derived from a mixture of a certain number of compounds of formula (4), where n can vary within the limits indicated above.

According to a second embodiment, compound A1 contains in its structure at least one group Si—X′, where X′ is a hydroxyl group or a hydrolyzable group, which may be chosen, without limitation, from the following groups: H, halogen, alkoxy, aryloxy, acyloxy, —NR¹R² where R¹ and R² independently denote a hydrogen atom, an alkyl group or an aryl group, and —N(R³)—Si where R³ denotes a hydrogen atom, an alkyl group or an aryl group.

According to this second embodiment of the invention, compound A1 preferably contains in its structure at least one Si—H group, i.e. it constitutes a silicon hydride. Preferably, the silicon atom of the group Si—X′ is not bonded to more than two non-hydrolyzable groups, such as alkyl or aryl groups.

Among the groups X′, the acyloxy groups preferentially have the formula —O—C(O)R⁴, where R⁴ is an aryl group, preferably a C6-C12 aryl group, optionally substituted with one or more functional groups, or an alkyl group, preferably a linear or branched C1-C6 alkyl group, optionally substituted with one or more functional groups and also possibly including one or more double bonds, such as phenyl, methyl or ethyl groups, the aryloxy and alkoxy groups have the formula —O—R⁵, where R⁵ is an aryl group, preferably a C6-C12 aryl group, optionally substituted with one or more functional groups, or an alkyl group, preferably a linear or branched C1-C6 alkyl group, optionally substituted with one or more functional groups and also possibly including one or more double bonds, such as phenyl, methyl or ethyl groups, the halogens are preferably F, Cl, Br or I, the groups X′ of formula —NR¹R² may denote an amino NH₂, alkylamino, arylamino, dialkylamino or diarylamino group, R¹ and R² independently denoting a hydrogen atom, an aryl group, preferably a C6-C12 aryl group, optionally substituted with one or more functional groups, or an alkyl group, preferably a linear or branched C1-C6 alkyl group, optionally substituted with one or more functional groups and also possibly including one or more double bonds, such as phenyl, methyl or ethyl groups, the groups X′ of formula —N(R³)—Si are attached to the silicon atom via their nitrogen atom and their silicon atom naturally includes three other substituents, where R³ denotes a hydrogen atom, an aryl group, preferably a C6-C12 aryl group, optionally substituted with one or more functional groups, or an alkyl group, preferably a linear or branched C1-C6 alkyl group, optionally substituted with one or more functional groups and also possibly including one or more double bonds, such as phenyl, methyl or ethyl groups.

The preferred acyloxy group is the acetoxy group. The preferred aryloxy group is the phenoxy group. The preferred halogen group is the Cl group. The preferred alkoxy groups are the methoxy and ethoxy groups.

In the second embodiment, compound A1 preferably includes at least one silicon atom bearing at least one alkyl group, preferably a linear or branched C1-C4 alkyl group, better still at least one silicon atom bearing one or two identical or different alkyl groups, preferably C1-C4 alkyl groups, and a group X′ (preferably a hydrogen atom) directly bonded to the silicon atom, X′ having the meaning indicated above. The preferred alkyl group is the methyl group. The vinyl group may also be used instead of an alkyl group. Preferably, the silicon atom of the group Si—X′ is directly bonded to at least one carbon atom.

Preferably, each silicon atom of compound A1 is not directly bonded to more than two groups X′, better still is not directly bonded to more than one group X′ (preferably a hydrogen atom) and better still each silicon atom of compound A1 is directly bonded to only one group X′ (preferably a hydrogen atom). Preferably, compound A1 has an Si/O atomic ratio equal to 1. Preferably, compound A1 has a C/Si atomic ratio <2, preferentially ≤1.8, better still ≤1.6 and even better still 1.5, 1.3 and optimally equal to 1. Also preferably, compound A1 has a 0/0 atomic ratio equal to 1. According to one embodiment, compound A1 does not include an Si—N group and better still does not include a nitrogen atom.

The silicon atom(s) of the precursor compound A1 of layer A are preferably solely bonded to alkyl groups, hydrogen and/or groups including an —O—Si or —NH—Si chain unit, so as to form an Si—O—Si or Si—NH—Si group. In one embodiment, compound A1 includes at least one group Si—O—Si—X′ or at least one group Si—NH—Si—X′, X′ having the meaning indicated above and preferably representing a hydrogen atom.

According to this second embodiment, compound A1 is preferably a compound of formula (3) in which at least one from among R′¹ to R′⁴ denotes a group X′ (preferably a hydrogen atom), X′ having the meaning indicated above.

According to this second embodiment, compound A1 is preferentially a cyclic polysiloxane of formula (5):

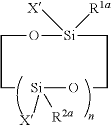

where X′ has the meaning indicated above and preferably represents a hydrogen atom, n designates an integer ranging from 2 to 20, preferably from 3 to 8, and R^{1a} and R^{2a} independently represent an alkyl group, preferably a C1-C4 alkyl group (for example the methyl group), vinyl group, aryl group or a hydrolyzable group. Nonlimiting examples of hydrolyzable groups X′ are the chloro, bromo, alkoxy, acyloxy, aryloxy and H groups. The commonest members belonging to this group are the tetra-, penta- and hexaalkylcyclotetrasiloxanes, preferably the tetra-, penta- and hexamethylcyclotetrasiloxanes, 2,4,6,8-tetramethylcyclotetrasiloxane (TMCTS) being the preferred compound. In some cases, layer A is derived from a mixture of a certain number of compounds having the above formula, where n can vary within the limits indicated above.

According to another embodiment, compound A1 is a linear alkylhydrosiloxane, better still a linear methylhydrosiloxane, for instance 1,1,1,3,5,7,7,7-octamethyltetrasiloxane, 1,1,1,3,5,5,5-heptamethyltrisiloxane or 1,1,3,3,5,5-hexamethyltrisiloxane.

The following compounds are nonlimiting examples of cyclic or noncyclic organic precursor compounds B of layer A in accordance with the second embodiment: 2,4,6,8-tetramethylcyclotetrasiloxane (TMCTS of formula (1)), 2,4,6,8-tetraethylcyclotetrasiloxane, 2,4,6,8-tetraphenylcyclotetrasi loxane, 2,4,6,8-tetraoctylcyclotetrasi loxane, 2,2,4,6,6,8-hexamethylcyclotetrasiloxane, 2,4,6-trimethylcyclotrisiloxane, cyclotetrasiloxane, 1,3,5,7,9-pentamethylcyclopentasiloxane, 2,4,6,8,10-hexamethylcyclohexasiloxane, 1,1,1,3,5,7,7,7-octamethyltetrasiloxane, 1,1,3,3,5,5-hexamethyltrisiloxane, tetramethyldisiloxane, tetraethoxysilane, vinylmethyldiethoxysilane, a hexamethylcyclotrisilazane, such as 3,4,5,6-hexamethylcyclotrisilazane or 2,2,4,4,6,6-hexamethylcyclotrisilazane, 1,1,1,3,5,5,5-heptamethyltrisiloxane, tris(trimethylsiloxy)silane (of formula (2)), 1,1,3,3-tetramethyldisilazane, 1,2,3,4,5,6,7,8-octamethylcyclotetrasilazane, nonamethyltrisilazane, tris(dimethylsilyl)amine, hexamethyldisilazane.

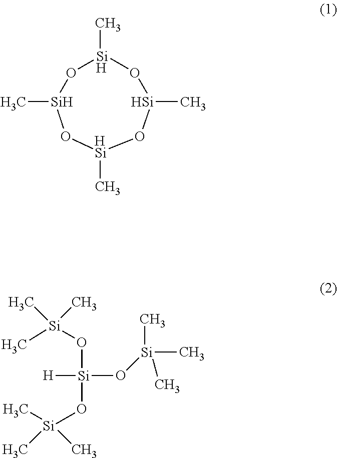

The precursor metal oxide B of layer A may be a low-refractive-index or high-refractive-index metal oxide, preferably a low-refractive-index metal oxide. These terms have been defined previously. It may be chosen from metal oxides and mixtures thereof suitable for the high- and low-refractive-index layers described above, or from substoichiometric metal oxides such as a substoichiometric silicon oxide, of formula SiOx, with x<2, x preferably ranging from 0.2 to 1.2, or a substoichiometric titanium oxide of formula TiOx, with x<2, x preferably ranging from 0.2 to 1.2.

The precursor metal oxide B of layer A preferably has a refractive index of less than or equal to one of the following values: 2.5; 2.4; 2.3; 2.2; 2.1; 2.0; 1.9; 1.8; 1.7; 1.6; 1.53; 1.5.

According to the preferred embodiment of the invention, the metal oxide B has a refractive index of less than or equal to 1.53 and better still less than or equal to 1.5. It is preferably silicon dioxide SiO₂ (silica), SiO, MgF₂, a substoichiometric silicon oxide, or mixtures thereof. The precursor metal oxide B is preferably a silicon oxide, ideally SiO₂.

Layer A of the final article preferably contains at least one metal oxide, preferably having a refractive index of less than or equal to 1.53. This metal oxide may be the same as the precursor metal oxide B used to form layer A and described above or be different therefrom, insofar as the process for depositing layer A may induce a modification of the precursor metal oxide such as an oxidation. It is preferably a silicon oxide, in particular the compound SiO₂. In this case, layer A preferably has a C/Si atomic ratio of less than or equal to 1. More generally, it preferably has a C/M atomic ratio of less than or equal to 1, where M represents all of the metals of the metal oxides present in layer A.

The use of at least one compound A1 to form layer A, which preferably includes Si—C and optionally Si—O bonds, makes it possible to benefit from improved mechanical properties with respect to the conventional low-refractive-index materials, such as SiO₂ or MgF₂, in particular the scratch resistance and the friction resistance of the substrates coated with the layers A according to the invention, which makes it possible to achieve levels hitherto inaccessible by the conventional technologies, such as the ion-assisted deposition of purely inorganic layers.

According to one embodiment of the invention, layer A comprises more than 80% by mass, preferably more than 90% by mass, of compounds derived from compound A1 and of the metal oxide according to the invention, relative to the total mass of layer A. According to one embodiment, layer A is formed exclusively of at least one metal oxide preferably with a refractive index of less than or equal to 1.53 and of at least one organic compound A1, with the exclusion of any other precursor. Preferably, layer A does not comprise any fluoro compound.

Preferably, layer A contains at least 50% by mass of metal oxides, typically from 50% to 100% by mass of metal oxides, which preferably have a refractive index of less than or equal to 1.53 relative to the mass of layer A, better still at least 50% by mass of silica. More preferably, layer A contains from 0% to 50% by mass of organic compounds A relative to the mass of layer A.

Preferably, layer A does not contain a separate metal oxide phase. Since layer A is formed by vacuum deposition, it does not comprise organosilicon compound hydrolyzate and thus differs from sol-gel coatings obtained via the liquid route.

The duration of the deposition process, the flow rates and the pressures are adjusted so as to obtain the desired coating thickness.

Layer A preferably has a thickness ranging from 5 to 500 nm or from 20 to 500 nm, more preferably from 25 to 250 nm or from 10 to 250 nm and better still from 30 to 200 nm. When it constitutes the outer layer of the interference coating, the organic-inorganic layer A preferentially has a thickness ranging from 60 to 200 nm. When it constitutes the layer making direct contact with the outer layer of the interference coating, layer A preferentially has a thickness ranging from 20 to 100 nm and better still from 25 to 90 nm.

Layer A preferably has a degree of porosity ranging from more than 0% to 90% by volume, preferably from 20% to 80%. The degree of porosity represents the void fraction in layer A of the invention.

Several methods may be used to calculate the porosity of the layer according to the invention. The ellipsometry method (Lorentz-Lorentz), the microbalance-ellipsometry method (ratio of rate of mass deposition/rate of deposition thickness), the infrared ellipsometry method (intensity of the SiO₂ peak). The method that is preferred in the context of the invention is the ellipsometry method using the Lorentz-Lorentz equation expressed in the case of a mixture of two materials in which the second material is formed of air. It is necessary to introduce the index of the dense material into this formula. In the present case, for the refractive index of dense (non-porous) silica, a value of 1.46 is retained.

The duration of the deposition process, the flow rates and the pressures are adjusted so as to obtain the desired coating thicknesses.

The nature of the precursor compounds employed, their respective amounts (which can be modulated by adjusting the flow rates evaporated) and the deposition conditions, in particular the duration of the deposition and the angle of incidence for the deposition of the metal oxide, are examples of parameters that a person skilled in the art will be able to vary in order to obtain an interference coating comprising at least one organic-inorganic layer having all of the desired properties, in particular with the aid of the examples of the present patent application.

After depositing the (two) precursors, layer A preferentially has an H/E ratio of greater than or equal to 0.09, better still greater than or equal to 0.10, even better still greater than or equal to one of the following values: 0.11, 0.12, 0.13 or 0.14, where H and E denote, respectively, the hardness of the material and the modulus of elasticity of the material, H and E being expressed in the same unit (for example MPa or GPa). In a noteworthy manner, the invention makes it possible to obtain layers A with a refractive index ranging from 1.35 to 1.40 and for which the H/E ratios range from 0.13 to 0.15.

The modulus of elasticity E of the material forming layer A and its hardness H are measured by an instrument-controlled penetration test (indentation), according to a method described in detail in the experimental section. If need be, reference will be made to the standard NF EN ISO 14577. The hardness H characterizes the ability of the material to withstand a permanent indentation or a deformation when it is brought into contact with an indenter under a compression load. The modulus of elasticity E (or Young's modulus, or storage modulus, or tensile modulus of elasticity) makes it possible to evaluate the ability of the material to deform under the effect of an applied force. The H/E ratio expresses the fracture resistance (resistance to crack propagation). Layer A and the articles according to the invention have good fracture resistance.

The modulus of elasticity E of the material forming layer A preferably ranges from 60 MPa to 15 GPa and preferably from 100 MPa to 10 GPa.

The layers A of the invention have greater elongations at break than those of the inorganic layers and can undergo deformations without cracking. For this reason, the article according to the invention has increased resistance to curvature.

By virtue of its improved mechanical properties, layer A, which may or may not form part of an interference coating, can in particular be applied to a single face of a semi-finished lens, generally its front face, the other face of this lens still needing to be machined and treated. The stack present on the front face of the lens will not be degraded by the treatments to which the rear face will be subjected during the curing of the coatings that will have been deposited on this rear face.

The organic-inorganic layer according to the invention typically has a low surface energy, quantified by a static contact angle with water of greater than or equal to 90°, better still greater than or equal to 100°, and even better still greater than or equal to 110°, 120°, 130° or 140°, and preferably ranging from 90 to 150° and better still from 90 to 140°. These static contact angles are readily obtained by working at the glancing incidences as defined in the present description (30-85°) and are proportionately higher the higher the angle of incidence of the vapor stream relative to the normal to the substrate. It is thus possible to obtain layers simultaneously having super-hydrophobic nature and a very low refractive index. Without wishing to be bound by a theory, the inventors think that these noteworthy hydrophobic properties result from the effect of the roughness of the surface of layer A resulting from their deposition method, which may be increased by employing a precursor organic compound A bearing alkyl, vinyl or aryl groups.

These hydrophobic properties of the layers A according to the invention are such that they are sparingly subject to water absorption and to reduction of the optical properties resulting therefrom, and are easier to wipe in the case of deposition of soiling on their surface.

In the present patent application, the static contact angles can be determined according to the liquid drop method, according to which a liquid drop having a diameter of less than 2 mm is deposited gently on a nonabsorbent solid surface and the angle at the interface between the liquid and the solid surface is measured.

Preferably, the mean reflection factor in the visible range (400-700 nm) of an article coated with a monolayer or multilayer interference coating comprising at least one layer A according to the invention, denoted Rₘ, is less than 2.5% per face, better still less than 2% per face and even better still less than 1% per face of the article. In an optimal embodiment, the article comprises a substrate, the two main surfaces of which are coated with an interference coating according to the invention, and has a total Rₘ value (cumulative reflection due to both faces) of less than 1%. Means for achieving such Rₘ values are known to a person skilled in the art.

The light reflection factor Rᵥ of an interference coating according to the invention is less than 2.5% per face, preferably less than 2% per face, better still less than 1% per face of the article, better still ≤0.75% and even better still ≤0.5%.

In the present application, the “mean reflection factor” Rₘ (mean of the spectral reflection over the entire visible spectrum between 400 and 700 nm) and the light reflection factor Rᵥ are as defined in the standard ISO 13666:1998 and are measured according to the standard ISO 8980-4.

In some applications, it is preferable for the main surface of the substrate to be coated with one or more functional coatings prior to the deposition of layer A or of the multilayer coating comprising layer A. These functional coatings conventionally used in optics can be, without limitation, a primer layer which improves the impact strength and/or the adhesion of the subsequent layers in the final product, an abrasion-resistant and/or scratch-resistant coating, a polarized coating, a photochromic or electrochromic coating or a colored coating, in particular a primer layer coated with an abrasion-resistant and/or scratch-resistant layer. These last two coatings are described in greater detail in patent application WO 2010/109154.

The article according to the invention may also include coatings, formed on layer A or the multilayer coating comprising it, which are capable of modifying its surface properties, such as a hydrophobic and/or oleophobic coating (antifouling top coat) or an anti-fogging coating. These coatings are preferably deposited on layer A or the outer layer of an interference coating. They are generally less than or equal to 10 nm in thickness, preferably from 1 to 10 nm in thickness and better still from 1 to 5 nm in thickness. They are described in patent applications EP1392613, WO 2009/047426 and WO 2011/080472, respectively.

Typically, an article according to the invention comprises a substrate successively coated with a layer of adhesion and/or impact-resistant primer, with an abrasion-resistant and/or scratch-resistant coating, with an optionally antistatic interference coating comprising at least one layer A according to the invention, and with a hydrophobic and/or oleophobic coating.

In another embodiment, the interference coating is a monolayer antireflective coating formed from layer A, and said layer constitutes the outer layer of the article according to the invention. In the case where the coating onto which layer A is deposited is a coating with a refractive index of 1.5, this monolayer A may advantageously constitute a quarter-wave layer given its low refractive index, which may be chosen to be of the order of 1.22 (n=√1.5=1.22).

The invention is illustrated in a nonlimiting manner by the examples that follow. Unless otherwise indicated, the thicknesses mentioned are physical thicknesses.

### EXAMPLES

### 1. General Procedures

The articles employed in the examples comprise an Orma® Essilor lens substrate with a diameter of 65 mm, a power of −2.00 diopters and a thickness of 1.2 mm, coated on its concave face with the impact-resistant primer coating and with the scratch-resistant and abrasion-resistant coating (hard coat), which are disclosed in the experimental section of patent application WO 2010/109154, and a layer A according to the invention.

The vacuum deposition machine is a Leybold Boxer Pro machine equipped with a specific sample holder allowing the simultaneous deposition of films at several angles of incidence, while at the same time ensuring rotation along the axis normal to the surface of the substrates. The lenses are attached with a metal stem or a Kapton tape to allow deposition at a large angle between the normal to the surface of the substrate and the vapor stream. The deposition machine is also equipped with an electron gun for the evaporation of the precursor metal oxide, with a thermal evaporator, with a KRI EH 1000 F ion gun (from the company Kaufman & Robinson Inc.), for the preliminary phase of preparation of the surface of the substrate with argon ions (IPC) and also for the deposition of layer A by ion bombardment (IAD), if necessary, and with a system for the introduction of liquid, which system is used when the precursor organic compound A of layer A is a liquid under standard temperature and pressure conditions (case of OMCTS and decamethyltetrasiloxane). This system comprises a tank containing the liquid precursor compound of layer A, resistances for heating the tank and the tubes connecting the tank of liquid precursor to the vacuum deposition machine, and a vapor flowmeter from the company MKS (MKS1150C), brought to a temperature of 30-120° C. during its use, depending on the flow rate of vaporized organic compound A, which preferably ranges from 0.01 to 0.8 g/min (the temperature is about 90-100° C. for a flow rate of 0.3 g/min of organic compound A).

The vapor of organic compound A exits from a copper pipe inside the machine, at a distance of about 30 cm from the ion gun. Flows of oxygen and optionally of argon are introduced into the ion gun, if it is used. Preferentially, neither argon nor any other noble gas is introduced into the ion gun.

The layers A according to the invention are formed by vacuum evaporation optionally assisted by a beam of oxygen ions and optionally argon ions during the deposition (evaporation source: electron gun) of octamethylcyclotetrasiloxane or decamethyltetrasiloxane, supplied by the company Sigma-Aldrich, and silica as metal oxide B, with a refractive index ≤1.53, used in the form of granules.

### 2. Procedures

The process for preparing the optical articles according to the invention comprises the introduction of the substrate, coated with the primer coating and with the anti-abrasion coating which are defined above, into the vacuum deposition chamber; preheating of the tank, the pipes and the vapor flowmeter to a temperature of 90° C. (˜15 min), a primary pumping step (mechanical pump), then a secondary pumping step (turbomolecular pump) for 400 seconds making it possible to obtain a secondary vacuum (<10⁻⁵ Torr, the pressure being read on capacitive and Penning gauges), a step of activation of the surface of the substrate with an argon ion beam (IPC: 1 minute, 100 V, 1 A, the ion gun being switched off or remaining in operation at the end of this step, depending on the case) followed by evaporation deposition of layer A, performed in the following manner.

The organic compound A is introduced into the chamber in gaseous form, at a controlled flow rate or partial pressure.

The metal oxide is preheated so as to be in a molten state and is then evaporated by means of an electron gun (the electron gun is switched on when the pressure of the gases in the chamber has stabilized), the shutter of the ion gun (if it is used) and that of the electron gun being opened simultaneously. Deposition is performed at a pressure of from 0.01 mTorr to 1 mTorr.

The thickness of the layers deposited was controlled in real time by means of a quartz microbalance, the rate of deposition being modified, if need be, by adjusting the current of the electron gun. Once the desired thickness has been obtained, the shutter(s) are closed, the ion gun (if it was in service) and the electron gun are switched off and the flows of gases (optionally oxygen and/or argon, and vapors of organic compound A) are stopped.

Finally, a ventilation step is performed, so as to recover the coated samples.

### 3. Characterizations

The measurements of the refractive index n were performed at a wavelength of 550 nm by variable-angle spectroscopic ellipsometry (VASE) using an ellipsometer (RC2, J.A. Woollam & Co., Inc.) equipped with a rotary double compensator. The refractive index is deduced from the dispersion relationship which models the optical response provided by the ellipsometric angles Ψ and Δ. For dielectric materials, such as SiO₂, the Tauc-Lorentz equation, known to those skilled in the art, satisfactorily models the optical properties of the layers deposited. All the measurements were performed at angles of incidence of 45°, 55°, 65° and 75° in a wavelength range of 190-1700 nm.

The mechanical properties of layer A were evaluated by nano-indentation measurement. To do this, the hardness H and the modulus of elasticity E of the material constituting layer A were evaluated by instrument-controlled penetration test (indentation), described below. This consists in causing a tip, also known as an indenter, of known geometry and mechanical properties, namely a Berkovich diamond tip, to penetrate under a force ranging from 100 μN to 10 000 μN into a layer of material A with a thickness of 500 nm deposited on a “silicon wafer” silica support and recording the force applied as a function of the depth of penetration h of the tip. These two parameters are measured continuously during a loading phase and an unloading phase, in order to deduce therefrom the mechanical properties of layer A.

The model used for calculating the hardness and the elastic modulus is that developed by Oliver and Pharr. The area of contact (Ac) for a Berkovich indenter is Ac=24.56×h_{c}². The hardness of the material is obtained by calculating the ratio of the maximum force applied to the surface area measured (area of contact Ac between the indenter and the sample),

$$\begin{matrix}H = \frac{{F}_{max}}{{A}_{c}} & {h}_{c} =\end{matrix} {h}_{max} - ɛ \cdot \frac{{F}_{max}}{S}$$

and the modulus of elasticity E is deduced from the indentation curve (force-penetration curve).

$$S = \frac{\partial F}{\partial h} = \frac{2}{\sqrt{π}} \cdot {E}_{r} \sqrt{{A}_{c}}$$

$$\frac{1}{{E}_{r}} = \frac{1 - {{υ}^{2}}_{i}}{{E}_{i}} + \frac{1 - {υ}^{2}}{E}$$

Er is the reduced modulus, Ei is the modulus of the indenter and ν is the Poisson coefficient. The measuring device used is a Tribolndenter TI950 device of the Hysitron brand.

The resistance of the articles to mechanical stresses representative of the wear of spectacle lenses (friction imposed by a tribometer) was also evaluated according to a test described in the following paragraph.

The measurement of the static contact angles with water was performed according to the liquid droplet method, in which a liquid droplet having a diameter of 5 μL is deposited gently on a nonabsorbent solid surface and the angle at the interface between the liquid and the solid surface is measured. The distilled water employed has a conductivity of between 0.3 μS and 1 μS at 25° C. The measurements were taken using an Attension Theta optical tensiometer and are the mean of three tests.

The image of FIG. 1 was obtained by scanning electron microscopy (SEM) on a Jeol JSM7600F machine equipped with a field-emission gun.

### 4. Results

Various flow rates of OMCTS precursor were employed (20, 15, 10 and 5 sccm). Ion assistance for the deposition of layer A was employed in examples C4-C6 and 17-28, with a flow rate of 20 sccm of O₂, and various anode currents (1 A or 3 A). Five deposition angles were tested: standard deposition at normal incidence (0°, comparative) and four depositions at a glancing incidence (angles of 86.5°, 76.7°, 67.6° and 59.5° relative to the normal).

Table 1 indicates the conditions for depositing the various layers A and also the optical and mechanical performance of the articles according to the invention or corresponding comparative articles, namely the refractive indices obtained as a function of the angle of incidence between the normal to the surface of the substrate and the stream of metal oxide vapors, and also certain values of the parameters H and H/E:

TABLE 1

| | Angle of | OMCTS | Oxygen flow | Anode | Layer A | | |
|---|---|---|---|---|---|---|---|
| | incidence | flow rate | rate (ion gun) | current | refractive | H | |
| Example | (°) | [sccm] | (sccm) | (ion gun) [A] | index | (GPa) | H/E |
| C1 | 0 | 20 | 0 | 0 | 1.44 | | |
| C2 | 0 | 15 | 0 | 0 | 1.45 | | |
| C3 | 0 | 5 | 0 | 0 | 1.46 | 1.7 | 0.15 |
| 1 | 59.5 | 20 | 0 | 0 | 1.435 | | |
| 2 | 59.5 | 15 | 0 | 0 | 1.42 | | |
| 3 | 59.5 | 10 | 0 | 0 | 1.395 | 0.77 | 0.15 |
| 4 | 59.5 | 5 | 0 | 0 | 1.38 | 0.74 | 0.14 |
| 5 | 67.6 | 20 | 0 | 0 | 1.41 | | |
| 6 | 67.6 | 15 | 0 | 0 | 1.40 | | |
| 7 | 67.6 | 10 | 0 | 0 | 1.36 | 0.51 | 0.14 |
| 8 | 67.6 | 5 | 0 | 0 | 1.33 | 0.31 | 0.11 |
| 9 | 76.7 | 20 | 0 | 0 | 1.39 | | |
| 10 | 76.7 | 15 | 0 | 0 | 1.355 | | |
| 11 | 76.7 | 10 | 0 | 0 | 1.32 | 0.19 | 0.12 |
| 12 | 76.7 | 5 | 0 | 0 | 1.27 | 0.07 | 0.12 |
| 13 | 86.5 | 20 | 0 | 0 | 1.38 | | |
| 14 | 86.5 | 15 | 0 | 0 | 1.35 | | |
| 15 | 86.5 | 10 | 0 | 0 | 1.285 | 0.10 | 0.11 |
| 16 | 86.5 | 5 | 0 | 0 | 1.18 | 0.03 | 0.16 |
| C4 | 0 | 15 | 20 | 1 | 1.46 | | |
| C5 | 0 | 5 | 20 | 1 | 1.47 | 2.2 | 0.13 |
| C6 | 0 | 5 | 20 | 3 | 1.49 | 2.5 | 0.15 |
| 17 | 59.5 | 15 | 20 | 1 | 1.41 | | |
| 18 | 59.5 | 5 | 20 | 1 | 1.365 | 0.96 | 0.11 |
| 19 | 59.5 | 5 | 20 | 3 | 1.405 | | |
| 20 | 67.6 | 15 | 20 | 1 | 1.395 | | |
| 21 | 67.6 | 5 | 20 | 1 | 1.34 | 0.56 | 0.09 |
| 22 | 67.6 | 5 | 20 | 3 | 1.395 | | |
| 23 | 76.7 | 15 | 20 | 1 | 1.38 | | |
| 24 | 76.7 | 5 | 20 | 1 | 1.30 | 0.25 | 0.10 |
| 25 | 76.7 | 5 | 20 | 3 | 1.36 | | |
| 26 | 86.5 | 15 | 20 | 1 | 1.375 | | |
| 27 | 86.5 | 5 | 20 | 1 | 1.285 | 0.17 | 0.09 |
| 28 | 86.5 | 5 | 20 | 3 | 1.375 | | |

The layers A of the articles according to the invention have lower refractive indices than the comparative articles, the refractive indices being proportionately smaller the higher the angle of incidence between the normal to the surface of the substrate and the stream of the metal oxide vapors.

A higher flow rate of organic compound A increases the refractive index of layer A due to a reduction in the directionality of the stream of metal oxide vapors. This effect is proportionately more pronounced the more glancing the angle of incidence.

The use of ion assistance during the deposition of layer A increases its refractive index. The refractive index of layer A decreases when the flow rate of organic compound A is reduced.

The layers A of the articles according to the invention have high H/E ratios, of the order of 0.15, which indicates very good mechanical strength. For comparative purposes, a layer deposited under the same conditions as the layers A of examples 13-16 but without using organic compound A1 (purely mineral layer of SiO₂ deposited at an angle of 86.5°) has a lower hardness H and an H/E ratio of only 0.03, and the anti-abrasion and/or anti-scratch coating used in the present stacks and disclosed in the experimental section of patent application WO 2010/109154 has a refractive index of 1.5, a hardness H of 0.7 GPa and an H/E ratio of 0.09. It was also observed that, for layers having the same refractive index, the layers A according to the invention are more elastic and are capable of withstanding higher stresses without plastic deformation than the corresponding inorganic layers deposited at a glancing angle.

The lenses of examples 24 and 27 were also characterized with a pin-on-disk tribometer from the company CSM, to evaluate the resistance of its layer A to mechanical stresses representative of the wear of spectacle lenses. For this test, the reflection spectrum of each of the lenses was first measured, rubbing was then performed with a silicone slug (8 shore 0) which presses on a chamois cloth placed on the lens. During the rubbing, the lens is moved under the cloth. 10 circular motions at a speed of 1 cm/s were performed, with increasing forces (loads) (1 N, 2 N, 5 N, 10 N), and the reflection spectrum of each lens was remeasured on conclusion of these stresses. The contact areas depend on the pressing force, and are 0.3 cm² for 1 N, 0.5 cm² for 2 N, 0.65 cm² for 5 N and 1.1 cm² for 10 N. It was found that the reflection spectra were not modified, which indicates that layer A was not impaired (no change in thickness, index or creation of defects). Layers based on the organic precursor decamethyltetrasiloxane give similar results. For comparative purposes, comparative layers obtained under the same conditions as the layers A of examples 24 and 27 but without employing any organic compound such as OMCTS or decamethyltetrasiloxane (purely mineral layer deposited at a glancing incidence) fail the test on using a load of 10 N or more. This demonstrates that the use of the organic compound A during the preparation of layer A markedly improves its mechanical strength.

The layers A according to the invention are highly hydrophobic and have static contact angles with water as high as 150° during deposition at an angle of incidence of 86.5°, and of the order of 130° during deposition at an angle of incidence of 67.6°. Contact angles as high as 115° may be achieved for an angle of incidence as low as 30°. These noteworthy hydrophobic properties result from the synergistic effect of the high roughness of the surface of layer A and of the presence on its surface of hydrophobic alkyl, vinyl or aryl groups. For their part, the silica layers deposited at a glancing angle are highly hydrophilic and have static contact angles with water of less than 10° during deposition at an angle of incidence ranging from 86.5° to 59.5°.

It is thus seen that the organic-inorganic layers A according to the invention have a very advantageous combination of optical and mechanical properties, which has never been reported hitherto.

1.-15. (canceled)

16. An article comprising a substrate comprising at least one main surface coated with a layer A of organic-inorganic nature of a material obtained by vacuum deposition of at least one metal oxide B and of at least one organic compound A1, said layer A having a refractive index of less than or equal to 1.45, wherein said metal oxide has been deposited by glancing-angle deposition.

17. The article of claim 16, wherein the organic compound A1 is an organosilicon compound.

18. The article of claim 17, wherein compound A1 includes at least one divalent group of formula: 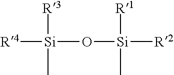
where R′1 to R′4 independently denote alkyl, vinyl, aryl or hydroxyl groups or hydrolyzable groups, or in that compound A1 corresponds to the formula: 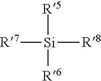
in which R′5, R′6, R′7 and R′8 independently denote hydroxyl groups or hydrolyzable groups, such as groups OR, in which R is an alkyl group.

19. The article of claim 16, wherein compound A1 is octamethylcyclotetrasiloxane, decamethyltetrasiloxane, 2,4,6,8-tetramethylcyclotetrasiloxane, hexamethyldisiloxane, decamethylcyclopentasiloxane, or dodecamethylpentasiloxane.

20. The article of claim 16, wherein the metal oxide B has a refractive index of less than or equal to 1.53.

21. The article of claim 16, wherein the metal oxide B is a silicon oxide.

22. The article of claim 16, wherein the glancing-angle deposition is performed at an angle between the normal to the surface of the substrate and the stream of vapors of said metal oxide of greater than or equal to 60°.

23. The article of claim 22, wherein the angle between the normal to the surface of the substrate and the stream of vapors of said metal oxide is greater than or equal to 65°.

24. The article of claim 22, wherein the angle between the normal to the surface of the substrate and the stream of vapors of said metal oxide is greater than or equal to 70°.

25. The article of claim 16, wherein layer A is a layer of an interference coating.

26. The article of claim 16, wherein the deposition of said layer A is assisted with a source of ions.

27. The article of claim 16, wherein said layer A has a refractive index of less than or equal to 1.40.

28. The article of claim 16, further defined as an optical lens.

29. The article of claim 28, further defined as an ophthalmic lens.

30. The article of claim 16, wherein said material has an H/E ratio of greater than or equal to 0.09, where H and E denote, respectively, the hardness of the material and the modulus of elasticity of the material.

31. The article of claim 30, wherein said material has an H/E ratio of greater than or equal to 0.10.

32. The article of claim 16, wherein said layer A has a columnar microstructure.

33. The article of claim 16, wherein layer A has a static contact angle with water of greater than or equal to 90°.

34. A process for manufacturing an article of claim 16, comprising at least the following steps:
supplying an article comprising a substrate having at least one main surface;
depositing onto said main surface of the substrate a layer A of organic-inorganic nature, by vacuum deposition of at least one metal oxide B and of at least one organic compound A1;
recovering an article comprising a substrate having a main surface coated with a layer A of a material with a refractive index of less than or equal to 1.45,
said metal oxide being deposited by glancing-angle deposition.
